(19) United States
(12) Patent Application Publication
(10) Pub. No.: US 2023/0314209 A1
(43) Pub. Date: Oct. 5, 2023

(54) PHOTODIODE STRUCTURE WITH DARK CURRENT INDICATION FUNCTION AND PHOTOELECTRIC SENSOR

(71) Applicants: Bin Shi, Beijing (CN); Fan Qi, Beijing (CN); Pengfei Cai, Beijing (CN)

(72) Inventors: Bin Shi, Beijing (CN); Fan Qi, Beijing (CN); Pengfei Cai, Beijing (CN)

(21) Appl. No.: 18/088,809

(22) Filed: Dec. 27, 2022

(30) Foreign Application Priority Data
Jan. 21, 2022 (CN) 2022100744779

(51) Int. Cl. G01J 1/42; G01J 1/44; H01L 31/0216; H01L 31/028; H01L 31/107

(52) U.S. Cl. CPC G01J 1/4228; G01J 1/44; H01L 31/02164; H01L 31/028; H01L 31/1075; G01J 2001/446

(57) ABSTRACT

The present invention provides a photodiode structure with a dark current indication function, including a photosensitive photodiode and a reference photodiode, where a photosensitive surface of the reference photodiode is provided with a light-blocking layer, and there is a fixed multiple relationship between dark currents of the photosensitive photodiode and the reference photodiode. The present invention further provides a photoelectric sensor, including a processing module and the photodiode structure. According to a structural design of the present invention, the photodiode structure may output two paths of current signals, so that an accurate signal photocurrent can be obtained only by subtracting the two paths of current signals in practice work, so as to finally achieve the objectives of eliminating the dark currents and reducing noise; and moreover, in the present invention, the dark currents of photodiodes are eliminated without increasing peripheral devices. Therefore, the present invention has the advantages of being simple in structure and low in cost, and further improving a photoelectric conversion efficiency.

### TECHNICAL FIELD

The present invention relates to the field of photoelectric detection equipment technologies, and in particular, to a photodiode structure with a dark current indication function and a photoelectric sensor.

### BACKGROUND

A photodiode, as a core device of a photoelectric sensor, may be used for distance detection, contact alarm, gesture recognition, and the like. In these applications, the photodiode receives scattered signal light and converts an optical signal into an electrical signal for output. A harvesting capability and photoelectric conversion efficiency of the photodiode for the scattered signal light are two key factors throughout the receiving process. To improve the foregoing two performances, the most common solution in a current design is to increase an aperture of the photodiode and a thickness of an absorbing layer, but increasing the aperture and thickening the absorbing layer will remarkably increase a dark current of the photodiode, thus increasing noise.

### SUMMARY

To solve the foregoing technical problems, the present invention provides a photodiode structure with a dark current indication function and a photoelectric sensor. The following provides a brief overview to gain a basic understanding of some aspects of the disclosed embodiments. The overview is not a general review, and is not intended to determine key/important components or describe the protection scope of these embodiments. The only objective thereof is to present some concepts in a simple form as a preface to the detailed explanations that follow.

The present invention employs the following technical solution:

In some optional embodiments, provided is a photodiode structure with a dark current indication function, including a photosensitive photodiode and a reference photodiode, where the reference photodiode is connected to the photosensitive photodiode in parallel via an electrode, a photosensitive surface of the reference photodiode is provided with a light-blocking layer, and there is a fixed multiple relationship between dark currents of the photosensitive photodiode and the reference photodiode.

Further, the photosensitive photodiode and the reference photodiode are photodiodes or avalanche photodiodes.

Further, the photosensitive photodiode and the reference photodiode each use silicon wafer or silicon on insulator (SOI) wafer as a substrate, a layer of N-doped silicon as a cathode connecting layer, a layer of P-doped silicon as an anode connecting layer, and use germanium, or silicon, or germanium-silicon, or other III-V materials as an absorbing layer. The light-blocking layer could be any material, such as metal, dielectric, or organic polymer layer, which could reflect the working wavelength light and thus protect the reference photodiode from being illuminated.

Further, when the photosensitive photodiode and the reference photodiode are Ge/Si avalanche photodiodes, a layer of intrinsic silicon is used as a multiplication layer, and a layer of P-doped silicon is used as a charge layer.

Further, an anode of the photosensitive photodiode is connected to an anode of the reference photodiode, or a cathode of the photosensitive photodiode is connected to a cathode of the reference photodiode; and the connection between the photosensitive photodiode and the reference photodiode refers to that the photosensitive photodiode and the reference photodiode share the same electrode or are connected by means of wire bonding.

In some optional embodiments, provided is a photoelectric sensor, including a processing module and a photodiode structure with a dark current indication function, where the processing module is configured to obtain two paths of current signals output by the photosensitive photodiode and the reference photodiode, and subtract between the two paths of current signals to eliminate dark currents.

Further, there is a fixed multiple relationship between a dark current Idₚₕₒₜₒₛₑₙₛᵢₜᵢᵥₑ of the photosensitive photodiode and a dark current Id_{reference} of the reference photodiode: Idₚₕₒₜₒₛₑₙₛᵢₜᵢᵥₑ=N×Id_{reference}; and
that there is a fixed multiple relationship between the dark currents of the photosensitive photodiode and the reference photodiode refers to any case in which the dark current of the photosensitive photodiode may be indicated by the reference photodiode, including but not limited to the following cases:
when the multiple relationship between the dark currents of the photosensitive photodiode and the reference photodiode does not vary with time and environment, N is an objective fixed constant and is stored in the processing module;
when the multiple relationship between the dark currents of the photosensitive photodiode and the reference photodiode varies with time and environment, but such variation is negligible, the processing module presets a fixed constant as an N value; and
when the multiple relationship between the dark currents of the photosensitive photodiode and the reference photodiode varies with time and environment, and such variation is non-negligible, the processing module generates and stores table data, and the table data includes N values corresponding to different environments and time.

The present invention has the following beneficial effects: According to a structural design of the present invention, the photodiode structure may output two paths of current signals, so that an accurate signal photocurrent can be obtained only by subtracting the two paths of current signals in practice work, so as to finally achieve the objectives of eliminating the dark currents and reducing noise; and moreover, the dark currents are eliminated without increasing peripheral devices. Therefore, the present invention has the advantages of being simple in structure and low in cost, and further improving photoelectric conversion efficiency.

### BRIEF DESCRIPTION OF DRAWINGS

FIG. 1 is schematic diagram of a photodiode structure with a dark current indication function according to the present invention; and

FIG. 2 is an equivalent circuit diagram of a photodiode structure with a dark current indication function according to the present invention.

### DETAILED DESCRIPTION OF EMBODIMENTS

The following description and accompanying drawings fully present specific implementation solutions of the present invention, so that a person skilled in the art can practice them. Other implementation solutions may include structural, logic, electrical, procedural and other variations. Embodiments merely typify possible variations. Unless expressly required, separate components and functions are optional, and the order of operation may be varied. Portions and features of some implementation solutions may be included in, or replaced with, those of other implementation solutions.

### Embodiment 1

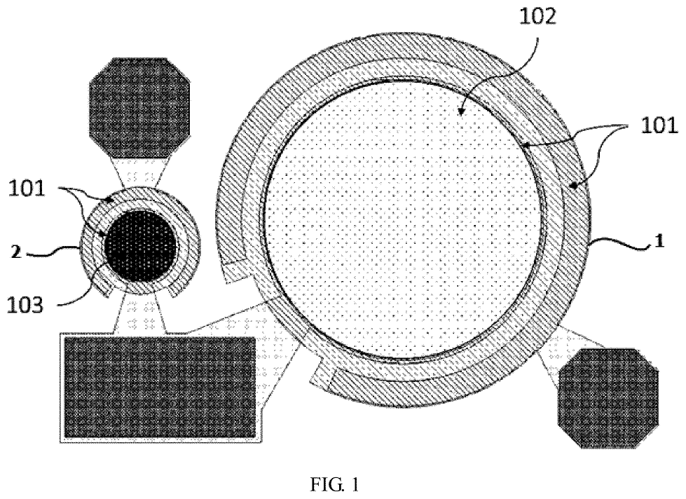

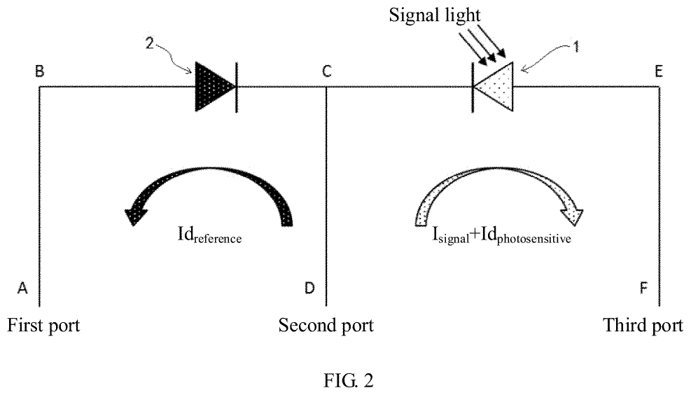

As shown in FIG. 1 and FIG. 2, the present invention provides a photodiode structure with a dark current indication function, including a photosensitive photodiode 1 and a reference photodiode 2.

The photosensitive photodiode 1 receives signal light via a photosensitive surface 102, and converts an optical signal into an electrical signal.

A photosensitive surface of the reference photodiode 2 is provided with a light-blocking layer 103. Therefore, the reference photodiode 2 does not receive the signal light, and is configured to output a dark current reference value to indicate the magnitude of the dark current of the photosensitive photodiode 1 in real time. The light-blocking layer 103 is a layer of opaque substance in a diode operating waveband, so that no stray signal light can penetrate, so as to ensure that the current output by the reference photodiode 2 at any time is a dark current of the reference photodiode, and that the dark current can be eliminated accurately subsequently.

The opaque substance used for the light-blocking layer 103 may be any medium, metal, structure, or the material through which the signal light cannot penetrate. Specifically, the signal light may be reflected or absorbed.

The reference photodiode 2 is connected to the photosensitive photodiode 1 in parallel via an electrode 101, an anode of the photosensitive photodiode 1 is connected to an anode of the reference photodiode 2, or a cathode of the photosensitive photodiode 1 is connected to a cathode of the reference photodiode 2. The connection between the photosensitive photodiode 1 and the reference photodiode 2 refers to that the photosensitive photodiode 1 and the reference photodiode 2 share the same electrode or are connected by means of wire bonding.

There is a fixed multiple relationship between the dark currents of the photosensitive photodiode 1 and the reference photodiode 2, that is, Idₚₕₒₜₒₛₑₙₛᵢₜᵢᵥₑ=N×Id_{reference}, where Idₚₕₒₜₒₛₑₙₛᵢₜᵢᵥₑ is the dark current of the photosensitive photodiode 1, and Id_{reference} is the dark current of the reference photodiode 2.

FIG. 2 illustrates the connection between the cathodes of the photosensitive photodiode 1 and the reference photodiode 2, and the connection between the anodes of the photosensitive photodiode 1 and the reference photodiode 2 has the same operating principle, and thus falls into the protection scope of the present invention. In FIG. 2, a voltage of a first port is V1, a voltage of a second port is V2, and a voltage of a third port is V3.

A bias voltage of the photosensitive photodiode 1 is a potential difference between the second port and the third port, that is, the bias voltage of the photosensitive photodiode is V2−V3; and a current output by the photosensitive photodiode 1 is a sum of a signal light current and the dark current of the photosensitive photodiode, that is, I_{signal}+Idₚₕₒₜₒₛₑₙₛᵢₜᵢᵥₑ, and a direction is D→C→E→F.

A bias voltage of the reference photodiode 2 is a potential difference between the second port and the third port, that is, the bias voltage is V2−V1; and a current output by the reference photodiode 2 is the dark current of the reference photodiode, that is, Id_{reference}, and a direction is D→C→B→A.

Therefore, the photodiode structure according to the present invention may output two groups of current signals: A first group of current signals is output by the third port as a signal output end, and an output current is I_{signal}+Idₚₕₒₜₒₛₑₙₛᵢₜᵢᵥₑ; and a second group of current signals is output by the first port as a reference end, and an output current is Id_{reference}. The two groups of current signals are simultaneously output to the outside of the photodiode structure for subsequent operation. Because Idₚₕₒₜₒₛₑₙₛᵢₜᵢᵥₑ×N×Id_{reference}, the dark current may be eliminated by subtracting in real time N×Id_{reference} from the current output by the signal output end, thus lowering noise caused by the dark current.

The photosensitive photodiode 1 and the reference photodiode 2 are photodiodes or avalanche photodiodes, and feature the following:
first, silicon is used as a substrate;
second, a layer of N-doped silicon is used as a cathode connecting layer;
third, a layer of P-doped silicon is used as an anode connecting layer;
fourth, a layer of germanium, or silicon, or germanium-silicon, or other III-V materials is used as an absorbing layer; and
fifth, when the photosensitive photodiode and the reference photodiode are avalanche photodiodes, a layer of intrinsic silicon is used as a multiplication layer, and a layer of P-doped silicon is used as a charge layer.

This ensures that the photodiode structure according to the present invention has a relatively high light-harvesting capacity and photoelectric conversion efficiency.

### Embodiment 2

The present invention provides a photoelectric sensor, including a processing module and the photodiode structure with a dark current indication function in Embodiment 1.

The processing module is configured to obtain two paths of current signals output by a photosensitive photodiode 1 and a reference photodiode 2, and subtract between the two paths of current signals to eliminate dark currents, thus finally obtaining an accurate signal light current.

In actual applications, the two groups of current signals output by the photodiode structure are collected by an external circuit, and input into the processing module for operation; and the processing module may be an arithmetic unit or a microcomputer processing system. There is a fixed multiple relationship between a dark current Idₚₕₒₜₒₛₑₙₛᵢₜᵢᵥₑ of the photosensitive photodiode 1 and a dark current Id_{reference} of the reference photodiode 2: Idₚₕₒₜₒₛₑₙₛᵢₜᵢᵥₑ=N×Id_{reference}.

That there is a fixed multiple relationship between the dark currents of the photosensitive photodiode 1 and the reference photodiode 2 refers to any case in which the dark current of the photosensitive photodiode 1 may be indicated by the reference photodiode 2, including but not limited to the following cases:
in a first case, when the multiple relationship between the dark currents of the photosensitive photodiode 1 and the reference photodiode 2 does not vary with time and environment, N is an objective fixed constant and is stored in the processing module, where the processing module is invoked for use in specific calculation;
in a second case, when the multiple relationship between the dark currents of the photosensitive photodiode 1 and the reference photodiode 2 varies with time and environment, but a variation is very tiny, so that such variation is negligible in actual calculation, the processing module presets a fixed constant as an N value which is stored in the processing module and may be invoked for use in specific calculation; and
in a third case, when the multiple relationship between the dark currents of the photosensitive photodiode 1 and the reference photodiode 2 varies with time and environment, and such variation is non-negligible, the processing module generates and stores table data which includes N values corresponding to different environments and time, where in specific calculation, subtraction is conducted after the N values are obtained by checking a table in real time.

The photodiode structure with the dark current indication function according to the present invention has the photosensitive photodiode 1 and the reference photodiode 2. While working, the photodiode structure outputs the two groups of current signals simultaneously. On the external circuit, the dark current components can be subtracted from a current at a signal end by performing real-time operation for the currents at the signal end and the reference end, thus eliminating the dark current and lowering noise. Therefore, a structural design according to the present invention makes a chip directly output the two paths of current signals, and eliminate the dark current by simple operation on the external circuit. On the premise of ensuring to output accurate signal photocurrent numerical, the present invention has the advantages of simple structure and low cost.

A person skilled in the art should further understand that electronic hardware, computer software or a combination thereof may be implemented in conjunction with various illustrative logic blocks, modules, circuits and algorithm steps described in the embodiments herein. To illustrate interchangeability between the hardware and the software, various illustrative parts, blocks, modules, circuits and steps have been described above generally in terms of functions thereof. Whether the functions are implemented as hardware or software depends on specific applications and design constraints applied to the entire system. Skilled technicians may implement the described functions in varying ways for each particular application, but such implementation decisions should not be interpreted as a departure from the protection scope of the present disclosure.

What is claimed is:

1. A photodiode structure with a dark current indication function, comprising a photosensitive photodiode and a reference photodiode, wherein
the reference photodiode is connected to the photosensitive photodiode in parallel via an electrode, a photosensitive surface of the reference photodiode is provided with a light-blocking layer, and there is a fixed multiple relationship between dark currents of the photosensitive photodiode and the reference photodiode.

2. The photodiode structure with a dark current indication function according to claim 1, wherein the photosensitive photodiode and the reference photodiode are photodiodes or avalanche photodiodes.

3. The photodiode structure with a dark current indication function according to claim 2, wherein the photosensitive photodiode and the reference photodiode each use silicon wafer or silicon on insulator (SOI) wafer as a substrate, a layer of N-doped silicon as a cathode connecting layer, a layer of P-doped silicon as an anode connecting layer, and use germanium, or silicon, or germanium-silicon, or other III-V materials as an absorbing layer. The light-blocking layer could be any material, such as metal, dielectric, or organic polymer layer, which could reflect the working wavelength light and thus protect the reference photodiode from being illuminated.

4. The photodiode structure with a dark current indication function according to claim 3, wherein when the photosensitive photodiode and the reference photodiode are Ge/Si avalanche photodiodes, a layer of intrinsic silicon is used as a multiplication layer, and a layer of P-doped silicon is used as a charge layer.

5. The photodiode structure with a dark current indication function according to claim 4, wherein an anode of the photosensitive photodiode is connected to an anode of the reference photodiode, or a cathode of the photosensitive photodiode is connected to a cathode of the reference photodiode; and
the connection between the photosensitive photodiode and the reference photodiode refers to that the photosensitive photodiode and the reference photodiode share the same electrode or are connected by means of wire bonding.

6. A photoelectric sensor, comprising a processing module and the photodiode structure with a dark current indication function according to claim 5, wherein
the processing module is configured to obtain two paths of current signals output by the photosensitive photodiode and the reference photodiode, and subtract between the two paths of current signals to eliminate dark currents.

7. The photoelectric sensor according to claim 6, wherein there is a fixed multiple relationship between a dark current Idₚₕₒₜₒₛₑₙₛᵢₜᵢᵥₑ of the photosensitive photodiode and a dark current Id_{reference} of the reference photodiode: Idₚₕₒₜₒₛₑₙₛᵢₜᵢᵥₑ=N×Id_{reference}; and
that there is a fixed multiple relationship between the dark currents of the photosensitive photodiode and the reference photodiode refers to any case in which the dark current of the photosensitive photodiode may be indicated by the reference photodiode, comprising but not limited to the following cases:
when the multiple relationship between the dark currents of the photosensitive photodiode and the reference photodiode does not vary with time and environment, N is an objective fixed constant and is stored in the processing module;
when the multiple relationship between the dark currents of the photosensitive photodiode and the reference photodiode varies with time and environment, but such variation is negligible, the processing module presets a fixed constant as an N value; and
when the multiple relationship between the dark currents of the photosensitive photodiode and the reference photodiode varies with time and environment, and such variation is non-negligible, the processing module generates and stores table data, and the table data comprises N values corresponding to different environments and time.
